(19) United States
(12) Patent Application Publication
(10) Pub. No.: US 2008/0293169 A1
(43) Pub. Date: Nov. 27, 2008

(54) LITHOGRAPHY EVALUATING METHOD, SEMICONDUCTOR DEVICE MANUFACTURING METHOD AND PROGRAM MEDIUM

(75) Inventors: Kazuo TAWARAYAMA, Yokosuka-shi (JP); Shunko Magoshi, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHI KAISHA TOSHIBA

(21) Appl. No.: 12/167,616

(22) Filed: Jul. 3, 2008

Related U.S. Application Data
(62) Division of application No. 10/994,242, filed on Nov. 23, 2004, now abandoned.

(30) Foreign Application Priority Data
Nov. 26, 2003 (JP) 2003-396009

(51) Int. Cl. H01L 21/66

(52) U.S. Cl. 438/16; 257/E21.53

(57) ABSTRACT

A lithography evaluating method comprises preparing a substrate, the substrate including a semiconductor substrate and a wiring structure including at least one wiring layer formed on the semiconductor substrate, partitioning the substrate into a plurality of regions to be evaluated, and obtaining a value of property relating to the wiring structure previously, and evaluating proximity effect on each of the plurality of regions to be evaluated based on the value of the property relating to the wiring structure.

### CROSS-REFERENCE TO RELATED APPLICATIONS

This application is based upon and claims the benefit of priority from prior Japanese Patent Application No. 2003-396009, filed Nov. 26, 2003, the entire contents of which are incorporated herein by reference.

### BACKGROUND OF THE INVENTION

1. Field of the Invention

The present invention relates to a lithography evaluating method, a lithography process and a program included in the semiconductor technology.

2. Description of the Related Art

The scattering that is generated in the exposure process using an electron beam includes a forward scattering, in which the electron beam incident within the resist is subjected to a multiple scattering so as to be expanded forward, and a back scattering, in which the electron beam arriving at the substrate below the resist is reflected from the surface of the substrate so as to be incident again on the resist.

Because of these forward scattering and back scattering, the electrons are scattered to reach the resist in the region that was not irradiated with the electron beam. As a result, the region that was not irradiated with the electron beam is also sensitized. The phenomenon is particularly prominent in a case where the patterns have a high density and the adjacent patterns are positioned close to each other, thus the phenomenon is called the proximity effects.

Various methods for suppressing the proximity effects are proposed in (for example, Japanese Patent Disclosure (Kokai) No. 09-186058, Japanese Patent Disclosure No. 07-078737 and Japanese Patent Disclosure No. 10-275762.) The conventional method disclosed in each of these patent documents is established on the basis that the substrate on which the pattern is to be written is formed of a homogenous material.

The reason is that, if the substrate is not formed of a homogenous material, the exposure conditions are changed for every material of the substrate, it results in the requirement of tremendous amounts of exposure data and the correction data. The tremendous amounts of the exposure data and the correction data takes a very long processing time, and the method is becomes impractical.

Incidentally, various films such as a SiO₂ film, an aluminum (Al) film, a titanium (Ti) film, a tungsten (W) film and a copper (Cu) film are formed on the surface of a semiconductor substrate through various film-forming processes. Further, various patterns such as a wiring pattern and a via pattern are formed on the semiconductor substrate as these films go through the various processing steps. That is, it is impossible for the actual substrate (the semiconductor substrate and various patterns) to be formed of a homogenous material.

In a case where the exposure treatment is applied to the actual substrate by the conventional method referred to above, the exposure conditions are determined for convenience on the assumption the actual substrate is formed of a homogenous material, and are not determined in accordance with the materials of the underlying layers of the substrate.

Therefore, the back scattering intensity of the electrons from the substrate is rendered nonuniform so as to give rise to the problem that the proximity effects cannot be evaluated accurately in a certain location, though the proximity effects can certainly be evaluated accurately in another location on the substrate. Particularly, in the location where a wiring layer formed of a heavy metal such as Cu or W is included in the under layer (underlying surface), the back scattering intensity is rendered abnormally high compared with the other location. It follows that the evaluation of the proximity effects tends to be rendered inaccurate.

In the region where the proximity effects cannot be evaluated accurately, the correction of the proximity effects is rendered insufficient. As a result, a structural defect such that a pattern having a desired size cannot be formed is generated on the region where the proximity effects is not evaluated accurately.

### BRIEF SUMMARY OF THE INVENTION

According to an aspect of the present invention, there is provided a lithography evaluating method comprising: preparing a substrate, the substrate including a semiconductor substrate and a wiring structure including at least one wiring layer formed on the semiconductor substrate; partitioning the substrate into a plurality of regions to be evaluated; and obtaining a value of property relating to the wiring structure previously, and evaluating proximity effect on each of the plurality of regions to be evaluated based on the value of the property relating to the wiring structure.

According to another aspect of the present invention, there is provided a lithography evaluating method comprising: preparing a substrate, the substrate including a semiconductor substrate and a wiring structure including at least one wiring layer formed on the semiconductor substrate; and obtaining a relationship between property relating to the number and thickness of the at least one wiring layer and property relating to reflection energy on a surface of the substrate of charged particles reflected on the wiring structure when a resist formed on the substrate is irradiated with a charged particle beam previously, and obtaining a relationship between size error of a resist pattern to be formed on the substrate by lithography process using a charged particle beam and value of the property relating to the number and thickness of the at least one wiring layer based on the property relating to the number and thickness of the at least one wiring layer and the property relating to the reflection energy on the surface of the substrate of charged particles.

According to another aspect of the present invention, there is provided a lithography evaluating method comprising: preparing a substrate, the substrate including a semiconductor substrate and a wiring structure including at least one wiring layer formed on the semiconductor substrate; partitioning the substrate into a plurality of regions to be evaluated; and evaluating proximity effect on each of the plurality of regions to be evaluated based on a relationship between size error of a resist pattern to be formed on the substrate by lithography process using a charged particle beam and a value of property relating to the number and thickness of the at least one wiring layer.

According to an aspect of the present invention, there is provided a semiconductor device manufacturing method comprising: preparing a substrate, the substrate including a semiconductor substrate and a wiring structure including at least one wiring layer formed on the semiconductor substrate; partitioning the substrate into a plurality of regions to be evaluated; obtaining property relating to reflection energy on a surface of the substrate of charged particles reflected on the wiring structure when a resist film formed on the substrate is irradiated with a charged particle beam; evaluating proximity effect on each of the plurality of regions to be evaluated based on a value of the obtained property; and correcting the resist pattern based on the evaluated proximity effect so as to permit the resist pattern formed of the resist to have a predetermined size.

According to an aspect of the present invention, there is provided a computer program product configured to store program instructions for execution on a computer system enabling the computer system to perform the operations of: reading in data relating to a substrate, the substrate including a semiconductor substrate and a wiring structure including at least one wiring layer formed on the semiconductor substrate; partitioning the substrate into a plurality of regions to be evaluated; and obtaining a value of property relating to the number and thickness of the at least one wiring layer included in the wiring structure previously and evaluating proximity effect on each of the plurality of regions to be evaluated.

According to another aspect of the present invention, there is provided a computer program product configured to store program instructions for execution on a computer system enabling the computer system to perform the operations of: reading in data relating to a substrate, the substrate including a semiconductor substrate and a wiring structure including at least one wiring layer formed on the semiconductor substrate; and

obtaining a relationship between property relating to the number and thickness of the at least one wiring layer and property relating to reflection energy on a surface of the substrate of charged particles reflected on the wiring structure when a resist formed on the substrate is irradiated with a charged particle beam previously, and obtaining a relationship between size error of a resist pattern to be formed on the substrate by lithography process using a charged particle beam and value of the property relating to the number and thickness of the at least one wiring layer based on the property relating to the number and thickness of the at least one wiring layer and the property relating to the reflection energy on the surface of the substrate of charged particles.

### BRIEF DESCRIPTION OF THE SEVERAL VIEWS OF THE DRAWING

FIG. 1 is a cross sectional view showing a substrate that is to be evaluated;

FIG. 2 is a graph showing the relationship between the thickness of the W wiring layer formed in the substrate to be evaluated and the back scattering coefficient η;

FIGS. 3A and 3B are a plan view and a cross sectional view of the substrate to be evaluated;

FIG. 4 is a flow chart showing the evaluating method of the electron beam lithography for an embodiment;

FIG. 5 shows a partitioning mode of the substrate to be evaluated;

FIG. 6 is a cross sectional view for explaining the number of layers of a Cu wiring that is not adopted;

FIG. 7 is a graph showing the relationship between the dimensional error and the number of wiring layers;

FIG. 8 is a cross sectional view showing a substrate having four wiring layers;

FIG. 9 is a graph showing the relationship between the dimensional error and the number of wiring layers in a case where the number of the wiring layers are four;

FIG. 10 is a cross sectional view showing the substrate including a plurality of sections differing from each other in the thickness of the W wiring (the number of W wiring layers);

FIG. 11 is a graph showing the change in the back scattering coefficient caused by the change in the thickness of the W wiring (the number of W wiring layers) examined by simulation in a case where a resist pattern is formed on the substrate of FIG. 10;

FIG. 12 is a cross sectional view showing the substrate including a plurality of sections differing from each other in the depth of the W wiring;

FIG. 13 is a graph showing the change in the back scattering coefficient caused by the change in the depth of the W wiring examined by simulation in a case where a resist pattern is formed on the substrate of FIG. 11;

FIG. 14 is a graph showing the relationship between the thickness of the W wiring and the back scattering coefficient and the relationship between the depth position of the W wiring and the back scattering coefficient on the same graph;

FIG. 15 is a flow chart showing the method of obtaining the dependency of the amount of the reflected energy on the thickness and depth of the wiring layer;

FIG. 16 is a plan view showing the substrate to be evaluated;

FIG. 17 is a cross sectional view along the line 17-17 given in the plan view shown of FIG. 16;

FIG. 18 shows the partitioning mode of the substrate to be evaluated;

FIG. 19 shows an arrangement of the multi-layer wiring of three layer;

FIG. 20 shows a diagram representing a relationship between the thickness of the wiring layer and the back scattering coefficient and a relative relationship between the depth of the wiring layer and the back scattering coefficient on the same graph;

FIG. 21 shows corresponding positions of the wiring layers with arrangement relations of configs. 2 to 4 in the FIG. 20;

FIG. 22 is a flow chart showing a semiconductor device manufacturing method of an embodiment; and

FIG. 23 is a drawing for explaining a computer program product of an embodiment.

### DETAILED DESCRIPTION OF THE INVENTION

Some embodiments of the present invention will now be described with reference to the accompanying drawings.

### First Embodiment

At first, an overview of an evaluating method of an electron beam lithography process of the present embodiment will now be described.

Formula (1) given below is the formula for quantitatively evaluating the proximity effects:

f(r)=1/(1+η)π·{1/βf²·exp(−r²/βf²)+η/βb²·exp(−r²/βb²) (1)

Formula (1) given above is called an image drawing intensity function (EID function). The meanings of the parameters given in formula (1) are as follows:

βf: forward scattering radius;

βb: back scattering radius;

η: back scattering coefficient;

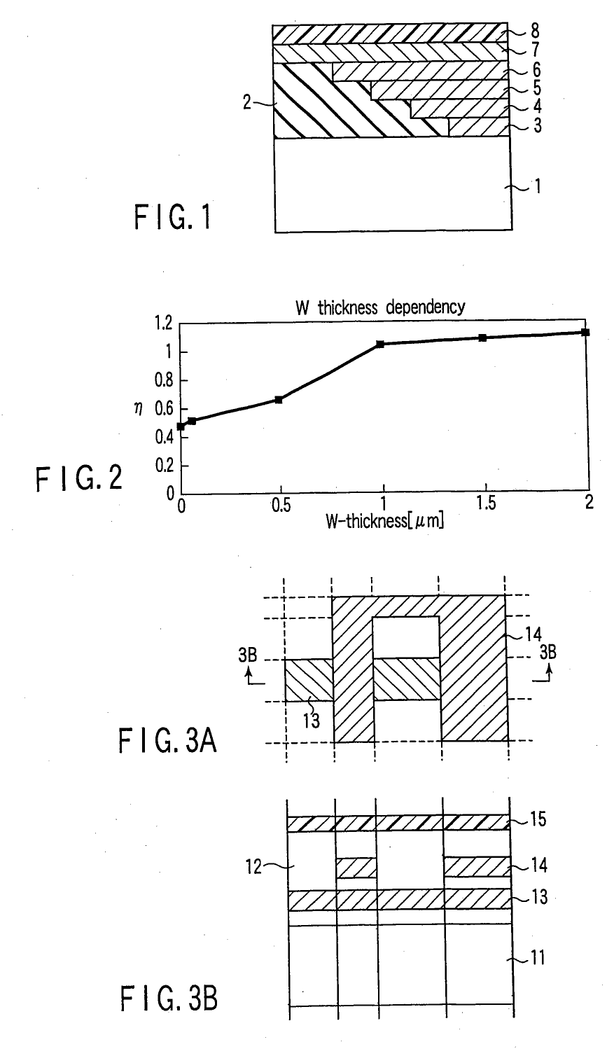

FIG. 1 is a cross sectional view showing the substrate to be evaluated including a silicon substrate 1, a silicon oxide (SiO₂) film 2, W wiring layers 3 to 6, and a Al wiring layer 7. A resist 8 is formed on the substrate. The silicon oxide film 2, the W wiring layers 3 to 6 and the Al wiring layer 7 form a wiring structure. Each of the W wiring layers 3 to 6 has a thickness of 0.5 μm. It follows that four regions in which the W wiring layers have a thickness of 0 μm, 0.5 μm, 1.0 μm, 1.5 μm, and 2.0 μm are included in the substrate (wiring structure).

FIG. 2 is a graph showing the relationship between the thickness of the W wiring layer in the substrate and the back scattering coefficient η. The reason that the dependency of the back scattering coefficient η on the thickness of the W wiring layer shows the such the result shown in FIG. 2 is considered as below. That is, if the thickness of the W wiring layer (the number of W wiring layers) increases, the amount of electrons (the amount of the reflected energy) which reach the substrate below the resist 8 and reflect on a surface of the substrate and come into the resist 8 again increases, as a result, it considered that the amount of the stored energy caused by the back scattering from the W wiring layer is increased. In other words, the increase in the thickness of the w wiring layer is equivalent to the increase in the density of the W wiring layers.

Therefore, in a case where a resist pattern is formed on the substrate shown in FIG. 1, the difference (dimensional error) between the actual size of the resist pattern formed on the substrate and design size of the resist pattern tends to be increased with increase in the back scattering coefficient η (with increase in the thickness or density of the W wiring layer).

So, if the difference between the actual size and design size of the resist pattern to be formed on the substrate caused by the difference of size of the underlying pattern such as the difference of thickness of the W wiring layer is obtained previously, it is possible to know the underlying pattern (underlying structure) that causes an increase in the size error and an increase in the error of the proximity effects correction

The back scattering coefficient η is varied mainly by the substance having a relatively high atomic weight. Therefore, it is possible to find out the portion where the size error is large, if the thickness and the position in the depth direction of the layer using the substance are known.

In general, a substance having a high atomic weight (heavy metal) such as W or Cu is used as the material of the wiring layer. Also, the device structure such as the thickness of each wiring layer for each era of the device is defined by the design rule. Various devices are designed in accordance with the design rule.

Therefore, it is possible to know the number of wiring layers or the thickness of each of the wiring layers formed of the heavy metal in the substrate for the lithography process by referring to the design rule. Further, it is possible to estimate the back scattering coefficient η based on the number of wiring layers or the thickness of each of the wiring layers, and it follows that the portion having a large error in proximity effects correction can be known.

The back scattering coefficient η is also dependent on the depth position of the wiring layer from the surface of the substrate. Therefore, it is possible to estimate more accurately the back scattering coefficient η in view of the depth position of the wiring layer from the surface of the wiring layer in addition to the number of wiring layers and the thickness of each of the wiring layers.

For example, in a case where the back scattering coefficient η is estimated on the basis of the number of layers of the wiring layer, the value given by the sum of “i” of Pi×ki, where Pi denotes the depth position of the i-th wiring layer as counted from the surface of the substrate and ki denotes the weight coefficient given to the depth position Pi, is used as the number of layers of the wiring layer. A larger weight coefficient is imparted to the position having a larger back scattering coefficient η. For example, a larger weight coefficient is imparted to the position closer to the surface of the substrate.

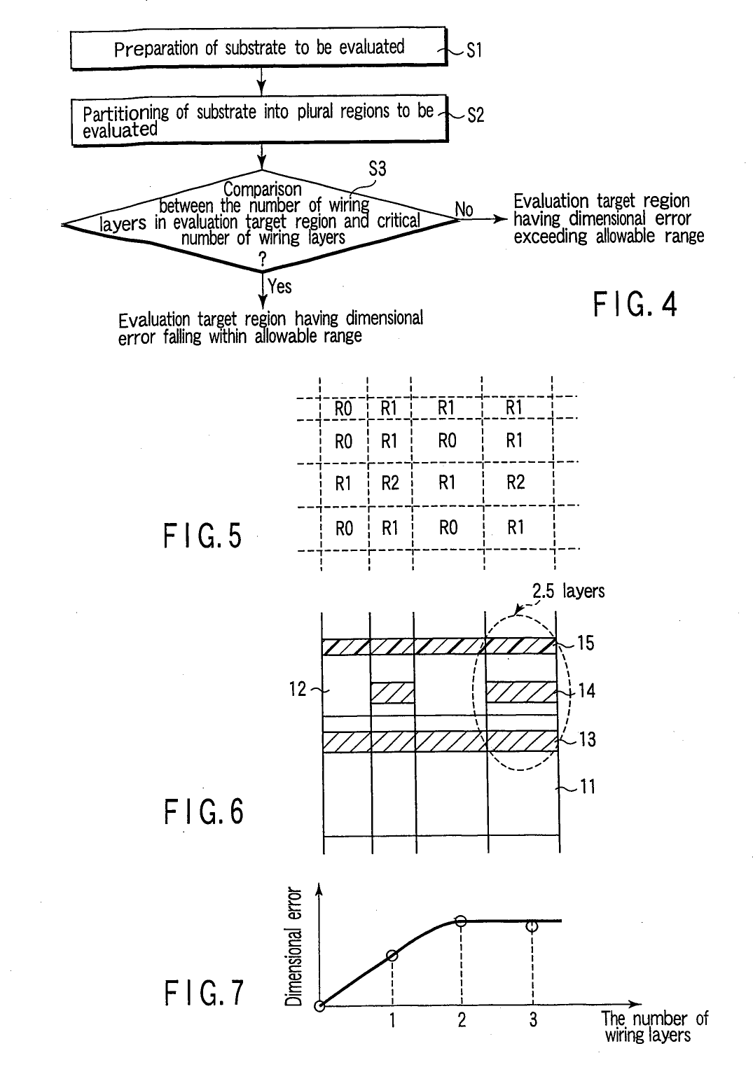

The evaluating method of the electron beam lithography of the present embodiment will now be described concretely. FIG. 3A is a plan view showing a substrate to be evaluated, and FIG. 3B is a cross sectional view along the line 3B-3B shown in FIG. 3A. FIG. 4 is a flow chart showing the evaluating method of the present embodiment.

At first, the substrate shown in FIGS. 3A and 3B is prepared (step S1). The substrate comprises a silicon substrate 11, a silicon oxide film (interlayer insulating film) 12, and first and second Cu layers 13, 14. A resist 15 is formed on the silicon oxide film 12.

A fine structure including a plurality of transistors (not shown) is formed on the surface of the silicon substrate 11. Each of the Cu wiring layers 13 and 14 is formed by the damascene process. Each of the Cu wiring layers 13 and 14 has a thickness of 0.3 μm.

In this case, the influences given by the fine structure are not taken into consideration for the sake of brevity. Since the influence of the fine structure to the back scattering coefficient η is sufficiently small compared with the influences of the Cu wiring layers 13, 14 to the back scattering coefficient η, a practical inconvenience is not brought about in the case where the influences given by the fine structure are not taken into account.

The silicon oxide film 12 of a single layer structure is shown in FIGS. 3A and 3B. However, the silicon oxide film is actually formed for every Cu wiring layer. Therefore, the silicon oxide film 12 shown in FIGS. 3A and 3B comprises a three-layered silicon oxide film in reality.

The resist 15 turns into a resist pattern used for forming a wiring groove in which the third Cu wiring layer is buried on a surface of the silicon oxide film 12 through the exposure step and the developing step.

Next, as shown in FIG. 5, the substrate is partitioned into 16 of 4×4 evaluation target regions (step S2). The evaluation target region (regions to be evaluated) is a unit region.

Here, the 16 evaluation target regions are classified into three kinds of regions. The three kinds of regions are a region R0 where the number of Cu wiring layers is zero, a region R1 where the number of wiring layers is 1, and a region R2 where the number of wiring layers is 2. That is, the 16 evaluation target regions are related to the number of Cu wiring layers.

Zero or a natural number (1, 2, . . . ) is selected as the number of Cu wiring layers, and a number differing from the natural number such as 2.5 layers is not selected as shown in FIG. 6. In other words, the 16 evaluation target regions are selected such that zero or a natural number of Cu wiring layers are formed inside the substrate.

Since Cu which is a material of the Cu wiring layers 13, 14 has a large atomic number compared with Si, the back scattering coefficient η is caused to differ greatly by the difference of the number of underlying Cu wiring layers. For that reason, unless the proximity effects correction is appropriately performed in accordance with the number of underlying Cu wiring layers, a pattern (here, the resist pattern for forming the third Cu wiring pattern) having a designed size is not formed.

The distribution of the number of layers of the Cu wiring layers 13, 14 (the number of wiring layers) in the substrate is acquired previously based on the data on the history of the process until the substrate to be evaluated is obtained and the data on the design of the device. Also, the back scattering coefficient η on each of the regions R0, R1 and R2 is obtained previously based on the known simulation, the basic experiment and the like. Further, the difference (dimensional error) between the actual size and the design size of the resist pattern to be formed on each of the regions R0, R1 and R2 also can be obtained previously based on the back scattering coefficient η.

The dimensional error is determined mainly by the number of Cu wiring layers (the number of wiring layers) which exist in the substrate. The relationship between the dimensional error and the number of wiring layers is shown in FIG. 7. Here, the dimensional error is defined to exceed the allowable dimensional error, if the number of wiring layers exceeds 1 (critical number of wiring layers).

Next, the magnitude relationship between the number of wiring layers in the 16 evaluation target regions and the critical number of wiring layers is compared (step S3).

As the result of comparison, the region to be evaluate whose number of wiring layers is larger than the critical number of wiring layers is a region having a large back scattering coefficient η is judged as a region having a large influence of the proximity effects, i.e., the evaluation target region whose dimensional error exceeds the allowable range. In this case, the proximity effects correction is repeated until the dimensional error falls within the allowable range (until YES in step S3 is reached). The specific method of performing the correction will be described herein later in the fourth embodiment.

On the other hand, the evaluation target region whose number of wiring layers is less or equal to the critical number of wirings is a region without a large back scattering coefficient η, then, it is judged as a region not having a large influence of the proximity effects, i.e., the evaluation target region whose dimensional error falls within the allowable range.

By employing the evaluating method according to the present embodiment described above, it is possible to extract the region which has a large influence of the proximity effects on the substrate by using the dependency of the proximity effects (back scattering coefficient η) on the thickness of the W wiring layer even in the case where the substrate is not formed of a homogenous material.

Further, since the evaluating method of the present embodiment can be performed easily, it is possible to extract promptly the region which has a large influence of the proximity effects on the substrate. Hereby, it is possible to correct accurately and promptly the proximity effects of the electron beam exposure.

Incidentally, in the present embodiment, the evaluation target region is related with the number of wiring layers, the evaluation target region can be related with the density of the Cu wiring layer (i.e., the density of the wiring layer).

In this case, the relationship between the dimensional error and the density of the wiring layer is obtained previously, then, the magnitude relationship between the density of the wiring layer in each of the evaluation target regions and the density of the wiring layer whose the dimensional error exceeds the critical dimensional error (the critical density of the wiring layer) is compared, and the proximity effects (dimensional error) on each of the evaluation target regions is evaluated.

The modification is effective in the case where a plurality of wiring layers differ from each other in thickness. Because the back scattering coefficient can be evaluated accurately even in the case where the total thickness of the wiring layers in the evaluation target regions with a small number of wiring layers is larger than the total thickness of the wiring layers in the evaluation with a large number of wiring layers.

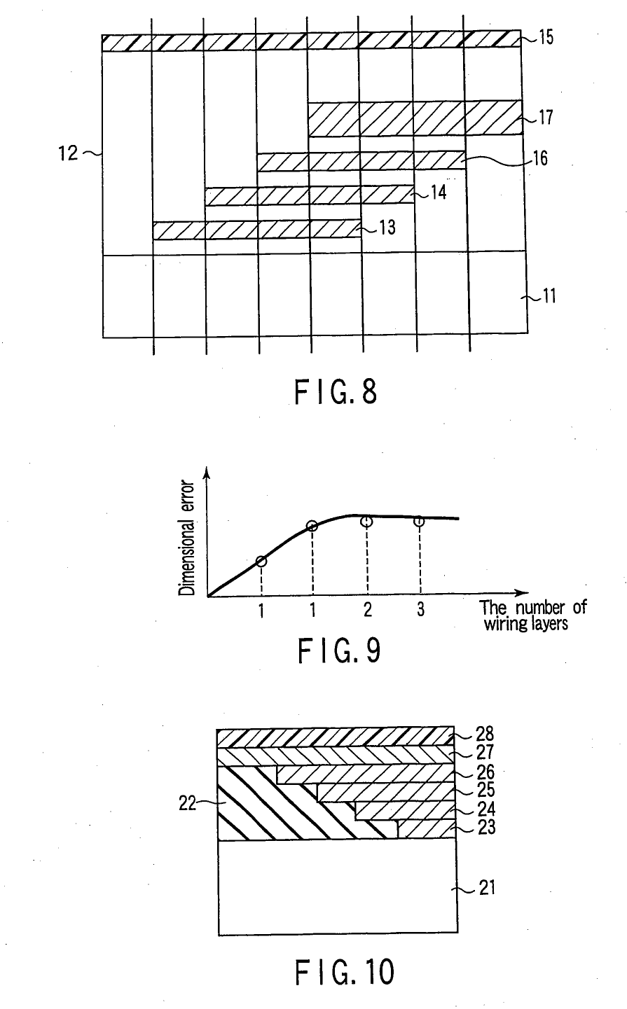

The present embodiment is explained in the case where the number of the layers comprising the heavy metal (heavy metal wiring layers) in the substrate to be evaluated is two, the embodiment in the case where the number of the heavy metal wiring layers in the substrate to be evaluated is three or more also performed as the present embodiment. FIG. 8 shows a cross sectional view of a substrate with three heavy metal wiring layers, FIG. 9 shows a relationship between the dimensional error and the number of wiring layers in the case where the number of the heavy metal wiring layers is three. FIGS. 8 and 9 correspond to FIGS. 3B and 7, respectively. In FIG. 8, a reference numeral 16 denotes a Cu wiring layer, and a reference numeral 17 denotes a wiring layer thicker than the Cu wiring layer 16. The wiring layer 17 is either a Cu wiring layer or an Al wiring layer.

### Second Embodiment

As described above, if the number of wiring layers (the density of the wiring layers) in the substrate shown in FIG. 1 is increased, the amount of electrons rebounded from the substrate (amount of the reflected energy) is increased, resulting in an increase in the stored energy caused by the back scattering from the underlying layer. And, with increase in the back scattering coefficient η, the difference between the actual size and the design size (dimensional error) of the resist pattern to be formed on the substrate increases.

Therefore, if the relationship between the structure in the substrate below the resist and the amount of the reflected energy caused by the electrons reflected on the underlying substrate structure is obtained previously, it is possible to know the construction of the underlying wiring that permits increasing the amount of the reflected energy even in the case where the substrate is not formed of a homogeneous material. Further, if the relationship between the amount of the reflected energy and the dimensional error is obtained previously, it is possible to extract accurately the region which has a large proximity effects on the substrate. Further, since the evaluating method of the present embodiment can be performed easily, it is possible to extract promptly the region which has a large influence of the proximity effects on the substrate. Hereby, the electron beam exposure can be corrected accurately and promptly.

And with regard to the region in which the amount of the reflected energy is large, i.e., the region in which the dimensional error caused by the proximity effects exceeds the allowable value, it is possible to form a pattern having a desired size with a very high accuracy on the substrate by performing exposure in which the energy is subtracted in an amount corresponding to the extra amount.

The evaluating method of the electron beam lithography of the present embodiment will now be described in concrete. FIG. 10 is a cross sectional view of a substrate to be evaluated. The substrate is such the substrate that the thickness of the W wiring layers (the number of W wiring layers) differs depending on the places. the substrate includes a silicon substrate 21, a silicon oxide film (interlayer insulating film) 22, W wiring layers 23 to 26, an Al wiring layer 27, and a resist 28. Each of the W wiring layers 23 to 26 has a thickness of 0.5 μm.

FIG. 11 is a graph showing the result of a simulation performed in an attempt to examine how the back scattering coefficient η is varied by the difference in thickness of the W wiring layer (difference in the number of W wiring layers) in the case where a pattern formed of the resist 28 (resist pattern) is formed on the substrate by an electron beam image writing apparatus. The result of FIG. 11 shows that with increase in the thickness of the W wiring layer (with increase in the number of W wiring layers), in other words, with increase in the density of the W wiring layers in the substrate, the amount of electrons rebounded from the substrate is increased, resulting in an increase in the stored energy caused by the back scattering.

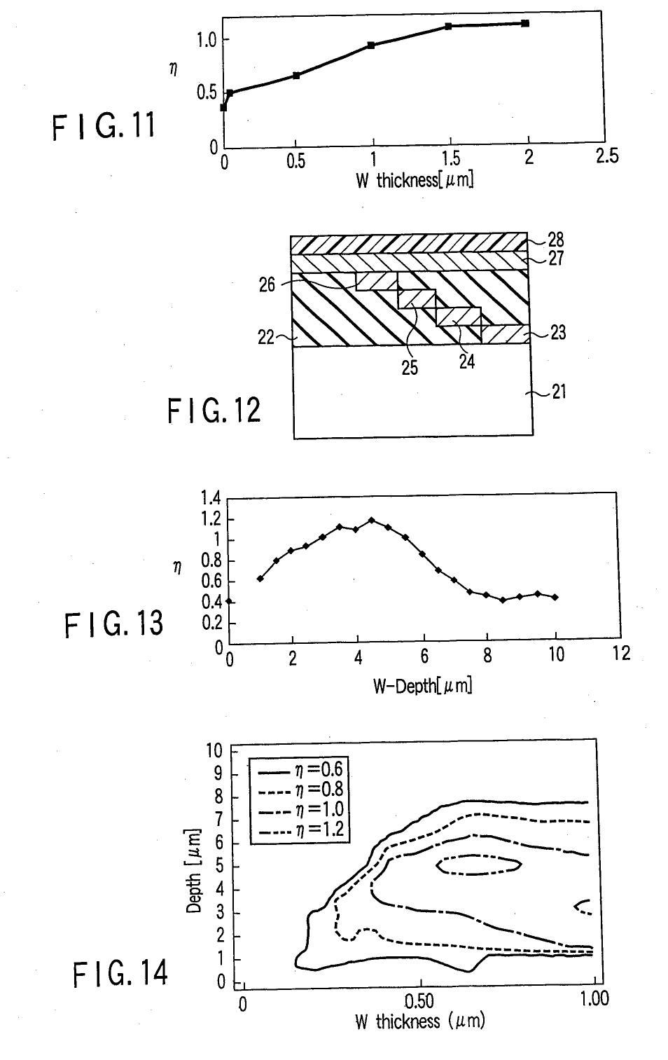

FIG. 12 is a cross sectional view showing the another substrate to be evaluated. The substrate is such the substrate that the thickness of the W wiring layers differs depending on the places. The portions in FIG. 12 which correspond to the portions shown in FIG. 10 are denoted by the reference numerals equal to those shown in FIG. 10, and detailed description thereof is omitted.

FIG. 13 is a graph showing the result of a simulation that is performed in an attempt to examine the change in the back scattering coefficient η caused by the difference in depth of the W wiring layers in the case where a pattern comprising the resist 28 (resist pattern) is formed on the substrate by using an electron beam image writing apparatus. From the FIG. 13, it is understand that the back scattering coefficient η is varied to have a maximal value in a certain depth position.

It has been found from FIGS. 12 and 13 that the back scattering coefficient η can be represented in the form of function F1 (Th) of the thickness (Th) of the W wiring layer and can also be represented in the form of function F2 (D) of the depth position (D) of the W wiring layer. It has also been found that the function F1 (Th) can be approximately represented by a numerical formula such as a polynomial expression of the thickness (Th) and the function F2 (D) can be approximately represented by a numerical formula such as a polynomial expression of the depth position (D).

FIG. 14 shows the relationship between the thickness (Th) of the W wiring layer and the back scattering coefficient (η) and the relationship between the depth position (D) of the W wiring layer and the back scattering coefficient (η) on the same graph. If the function F1 (Th) and the function F2 (D) are obtained, the back scattering coefficient (η) can be presented in the form of a function F (Th, D) of the thickness (Th) of the W wiring layer and the depth position (D) of the W wiring layer. The function F (Th, D) can be approximately represented by a numerical formula such as a polynomial expression of the thickness (Th) and the depth position (D) of the W wiring layer.

From this result, if the thickness and depth of the W wiring layer in the substrate (wafer) in a certain process step is known, the amount of the energy of the electrons reflected on the substrate can be obtained in the case where the substrate is irradiated with electrons by using an electron beam image writing apparatus.

The reflection energy (E) of the electrons reflected on the substrate can be considered as “E=f(η)” from the formula (1). That is, the formula given above can be written as follows:

E=F1′(Th); E=F2(D); E=F′(Th,D)

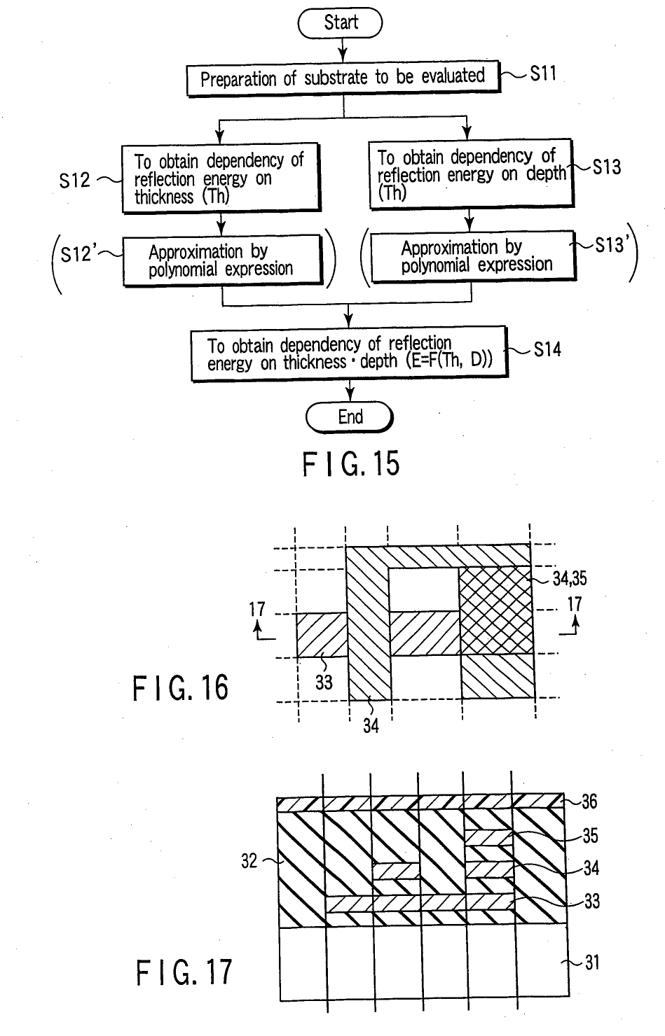

FIG. 15 is a flow chart showing the procedure (simulation) given above. The FIG. 15 will now be explained further. At first, a substrate (wafer) to be evaluated, which comprises a wiring structure including a multi-layered metal wiring layer is prepared (step S11).

Next, the relationship between the thickness of the metal wiring layer and the reflection energy and the relationship between the depth of the metal wiring layer and the reflection energy are obtained by the known simulation in respect to the substrate (steps S12 and S13). Thereafter, if necessary, the reflection energy E (Th) is approximately represented by a polynomial expression of the Th (step S12′), and the reflection energy E (D) is approximately represented by a polynomial expression of the D (step S13′).

Next, the dependency of the reflection energy of the electrons reflected on the substrate on the thickness and depth of the metal wiring layer is obtained from the relationship between the depth of the metal wiring layer and the obtained reflection energy and the obtained relationship between the thickness of the metal wiring layer and the reflection energy (step S14). In the case where the reflection energies E (Th) and E (D) are approximately represented a polynomial expressions, the reflection energy E (Th, D) can be approximately represented by a polynomial expression of the Th and D.

In the case where a resist pattern is formed on a substrate comprising a wiring structure including a heavy metal wiring such as a W wiring, an error is generated to the design size by an amount corresponding to the back scattering intensity of the electrons reflected on the substrate, i.e., corresponding to the reflecting energy of the electrons reflected on the substrate.

The reflection energy (E), as described above, can be estimated based on the thickness (Th) and the depth (D) of the W wiring layer existing in the substrate. Therefore, if the relationship between the reflection energy (E) and the size error (δCD) of the resist pattern to be formed on the substrate is known, the size error (δCD) can be estimated based on the thickness (Th) and the depth (D) of the W wiring layer existing in the substrate. That is, the resist pattern having a sufficiently small error relative to the design size can be formed.

FIG. 14 referred to previously alternatively means the dependency of the reflection energy (E) on the thickness (Th) and the depth (D) expressed in a three dimensional space (XYZ perpendicular coordinate system) in which the thickness (Th) of the metal wiring layer in the substrate is represented on the X-axis, the depth (D) of the metal wiring layer in the substrate is represented on the Y-axis, and the reflection energy (E) is represented on the Z-axis. The dependency can be expressed by using regression curve approximate formulas of a polynomial expression given below:

E=F1(Th), E=F2(D)

Therefore, it is understand that FIG. 14 denotes a contour map prepared by joining the points Ei having the same amount of the reflection energy in the regression curves E=F1 (Th) and E=F2 (D) so as to indicate the regions having the same amount of the reflection energy.

Next, the formation of a resist pattern having a dimension whose amount of deviation from the design size falls within an allowable range is considered.

At first, the threshold value (Eth) of the reflection energy on the substrate that permits the amount of deviation from the design size to fall outside the allowable range is determined. The thickness (Th) and the depth (D) satisfying the conditions of F1 (Th)>Eth and F2 (D)>Eth are obtained from the regression curve and the threshold value (Eth).

If a resist pattern is formed on a region of the substrate having the thickness (Th) of the metal wiring layer and the depth (D) of the metal wiring layer both satisfying the conditions, the resist pattern is caused to have size exceeding the allowable error for the design size.

### Third Embodiment

FIG. 16 is a plan view showing a substrate to be evaluated. FIG. 17 is a cross sectional view along the line 17-17 in the plan view of FIG. 16. FIGS. 16 and 17 show the substrate including a silicon substrate 31, a silicon oxide film (interlayer insulating film) 32, and wiring layers 33 to 35 of the first to third layer. A resist layer 36 is formed on the substrate.

A fine structure such as a plurality of transistors (not shown) are formed on the surface of the silicon substrate 31. The Cu wiring layers of the first to third layer are formed by damascene process. Each of the Cu wiring layers 33 to 35 has a thickness of 0.3 μm.

The resist 36 turns into a resist pattern used for forming a wiring groove in which the fourth Cu wiring layer is buried on a surface of the silicon oxide film 32 through the exposure step and the developing step.

The distribution of the number of Cu wiring layers (the number of wiring layers) in the substrate is obtained based on the data on the history of the process until the substrate to be evaluated is obtained and the data on the design of the device.

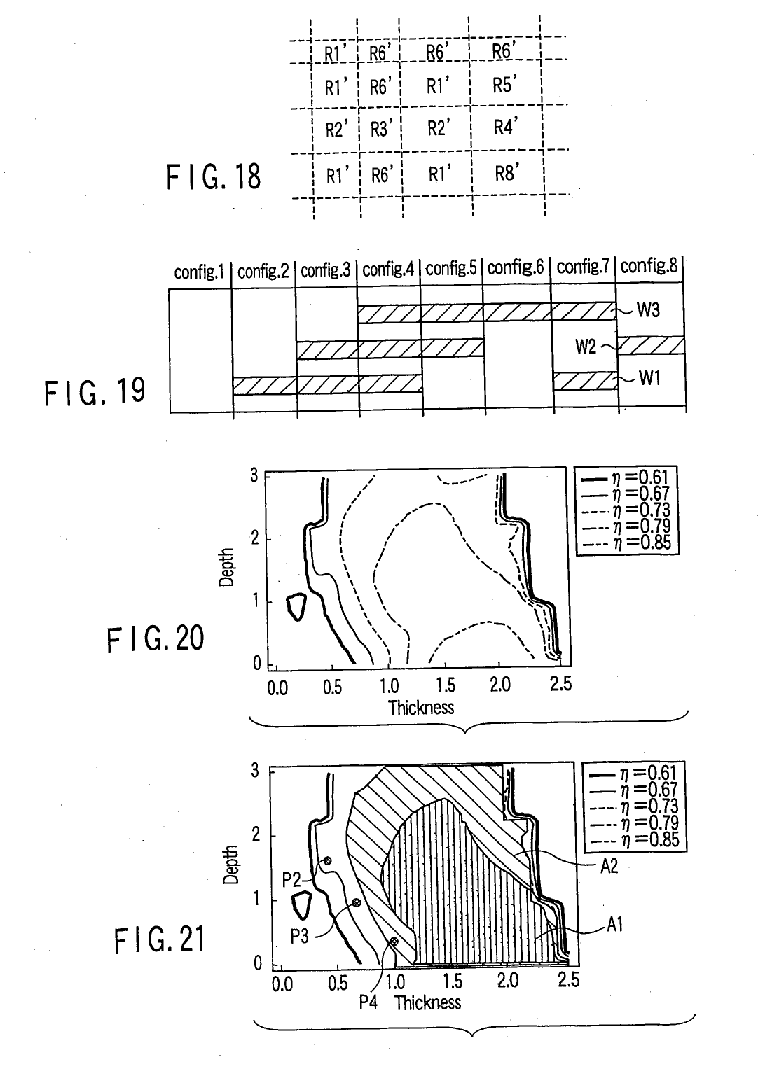

Next, as shown in FIG. 18, the substrate is partitioned into 16 of 4×4 evaluation target regions (step S2). The evaluation target region (regions to be evaluated) is a unit region.

In the case of a multi-layered wiring comprising three wiring layers, as shown in FIG. 19, there are 8 kinds of the arrangement relations configs. 1 to 8 in the wiring layers W1 to W3.

Next, the 16 evaluation target regions are classified into 6 regions (6 unit regions) R1′ to R6′ in accordance with the arrangement relation of the Cu wiring layers 33 to 35 in the evaluation target regions.

Region R1′ includes the arrangement relation of config. 1, region R2′ includes the arrangement relation of config. 2, region R3′ includes the arrangement relation of config. 3, region R4′ includes the arrangement relation of config. 4, region R5′ includes the arrangement relation of config. 5, and region R6′ includes the arrangement relation of config. 8, respectively.

The interlayer insulating film 32 is an insulating film containing SiO₂ as a main component, and Cu used as the wiring material has a large atomic number, compared with Si and O. So, if the arrangement relations of the Cu wiring layers 33 to 35 differ in the each of the regions of the substrate in the lithography step, the density, the depth, and the like of the underlying Cu wiring differ, then the back scattering radius and the back scattering coefficient also differ. Unless the proximity effects correction performed appropriately in accordance with the arranging relation of the underlying Cu wiring layer, image writing pattern (here, a resist pattern used for forming a fourth Cu wiring pattern) having a desired size is not formed.

The back scattering radius and the back scattering coefficient in each of the arranging relations of configs. 1 to 8 can be obtained by a known simulation, a basic experiment and the like.

Since the metal wiring layer reflects electrons as described previously, the amount of the energy imparted to the resist coated on the upper layer is varied in accordance with the depth and the thickness of the metal wiring layer.

FIG. 20 shows a diagram representing the relationship between the thickness of the wiring layer in the substrate of the present embodiment and the back scattering coefficient and the relationship between the depth of the wiring layer in the substrate of the present embodiment and the back scattering coefficient on the same graph. FIG. 20 corresponds to FIG. 14, and represents a contour map of the back scattering coefficient η from the thickness and depth of the metal wiring layer existing in a certain region on the substrate (wafer) to the certain region, that is, contour line in respect to the intensity of the reflection energy of the electrons reflected on the substrate.

FIG. 21 shows corresponding positions of the wiring layers with arrangement relations of configs. 2 to 4 in the FIG. 20. In FIG. 21, P2 to P4 denote the wiring layers having the arrangement relations of configs. 2 to 4, respectively. The total thickness of the wiring layers is represented on the abscissa in the graph of FIG. 20 and the depth of the uppermost wiring layer is represented on the ordinate in the graph of FIG. 20. For simplicity, only the wiring layers W1 to W3 having the arrangement relations of configs. 2 to 4 are shown, similarly, the wiring layers W1 to W3 having the arrangement relations of configs. 1 and 5 to 8 can be shown.

If the energy of electrons reflected on the substrate have a high intensity, that is, if the back scattering coefficient of the electrons is large, the amount of deviation of the resist pattern actually formed on the substrate from the design size (the dimensional error: δCD) increases.

To be more specific, there is a relationship of “δCD=k1*η+k2”, where each of k1 and k2 denotes a coefficient.

If the relationship between the back scattering coefficient of the substrate and the size deviation amount (δCD) of the resist pattern is obtained previously in this manner, it is possible to know the underlying substrate structure (arrangement relation) which causes the size deviation amount δCD of the resist pattern to be increased.

It is possible to obtain the range of the corresponding back scattering coefficient based on the size error of the resist pattern to be formed in view of the relational expression. The intensity of the back scattering, which fails to fall within the allowable range, is represented by, for example, region A1 or region A2 shown in FIG. 21. The allowable size error corresponding to region A1 is severer than the allowable size error corresponding to region A2. In FIG. 21, in the case of region A2, as the P4 is included in region A2 in FIG. 21, the size deviation amount δCD of the resist pattern to be formed on the region included in the wiring layer having the arrangement relation of config. 4 is expected to be larger than the allowable size error.

A region corresponding to the intensity of the back scattering failing to fall within an allowable range (region outside the allowable range) is set in FIG. 21 based on the value of the size error of the resist pattern obtained from the design rule or the process capacity. It is judged whether or not there is an evaluation target region (unit region) as shown in, for example, FIG. 5 or FIG. 18 in the region outside the allowable range. The region corresponding to the evaluation target region (unit region) that is present in the region outside the allowable range is called a dangerous portion region (attention requiring region).

The dangerous portion region is a region where the reflection energy of the electrons reflected on the substrate is large. So, the size of the portion corresponding to the dangerous portion region of resist pattern deviates from the design size, and has a high possibility to exceed the allowable error range.

In this manner, FIG. 21 shows the region where the reflection energy in the substrate is large in a easily understandable form. Also, by using FIG. 21, a region where the reflection energy in the substrate can be examined. Further, it is confirmed that the dangerous portion region can be by using FIG. 21. Further, the use of FIG. 21 makes it possible to confirm promptly in which portion of the substrate (wafer) the dangerous portion region exists.

### Fourth Embodiment

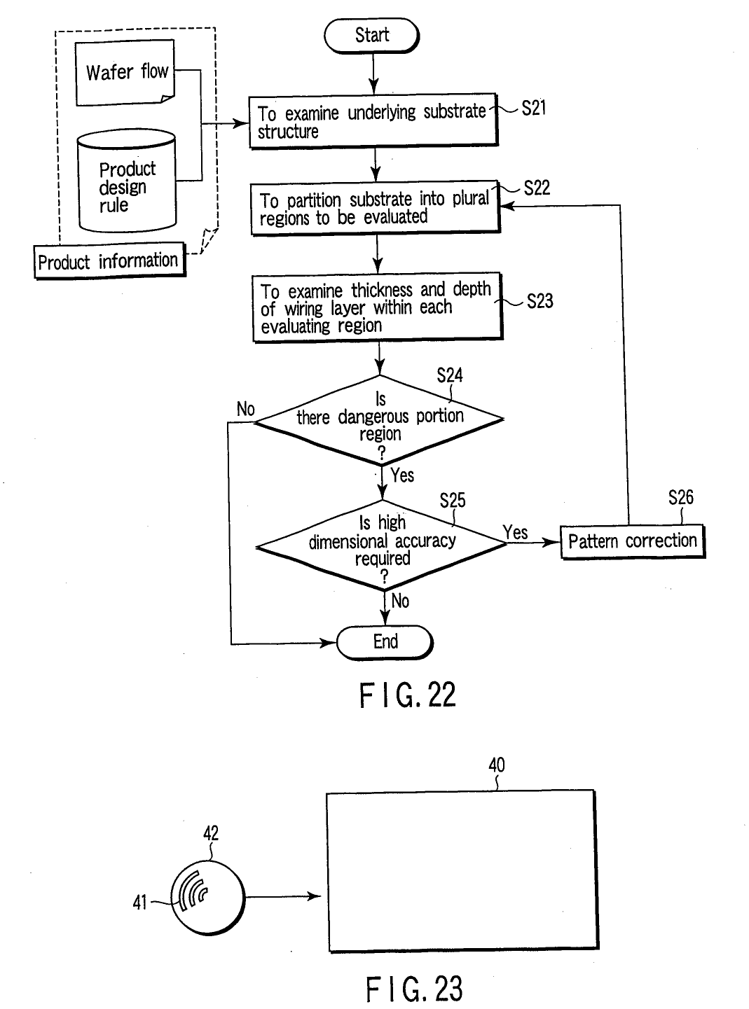

FIG. 22 is a flow chart showing the semiconductor device manufacturing method according to the fourth embodiment.

The device size such as the thickness of the wiring layer for each era of the device (product) that is to be manufactured is specified in the design rule of the product. Therefore, it is possible to know the number of wiring layers included in the substrate (wafer) or the thickness of each of the wiring layers, and the position in the depth direction of the wiring layer for each lithography process by referring to the design rule. The intensity of the reflection energy of the electrons owned by the substrate that is to be subjected to the lithography process can be obtained from the acquired number of wiring layers or thickness of the wiring layers and the position of the wiring layer in the depth direction. In manufacturing the device, a series of these process steps are described previously in the procedure manual that is called a wafer flow.

At first, an arrangement relation (underlying substrate structure) of the wiring layers made of a heavy metal such as Cu wiring layers in the substrate in each lithography step is examined by referring to the wafer flow (step S21).

Next, the substrate in each of the lithography step is partitioned into a plurality of evaluating regions (unit regions) based on the arrangement relation of the wiring layers (underlying substrate structure (step S22).

Next, the thickness and depth of the wiring layer in each of the evaluating region is examined (step S23).

Next, it is judged whether or not there is an evaluating region corresponding to the dangerous portion region (step S24). To be more specific, the reflection energy (E) is compared with the threshold value (Eth) in each of the evaluating region based on the thickness and depth of the wiring layer, and the evaluating region satisfying the condition of E>Eth is extract as the dangerous portion region.

Next, it is judged based on the procedure manual whether or not exist a region (warning region) where a pattern having a small margin and requiring a high dimensional accuracy is formed in the evaluation target regions (unit regions) extracted as the dangerous portion regions (step S25).

The warning region is a region whose possibility that a pattern having the error size exceeding the allowable value is high. Therefore, in the case where the warning region is found, correction is applied to the pattern (pattern to be corrected) formed on the warning region (step S27).

The correcting method of the pattern to be corrected will now be described. As described above, the amount of the reflection energy of the electrons reflected on the substrate in the evaluation target regions is known. The deviation amount (δCD) of the upper resist layer is obtained from the reflection energy. So, it is possible to form a resist pattern as designed by varying the size of the pattern to be corrected in an amount corresponding to the deviation amount (δCD) even if there is the reflection energy of the electrons reflected on the substrate. That is, the pattern that is written on the warning region (image writing pattern) is varied, thereby, the pattern design is varied. Also, it is similarly possible to form a resist pattern as designed by varying the exposure amount of the resist on the warning region in an amount corresponding to the deviation amount (δCD) in stead of varying the image writing pattern.

After the correction of the pattern to be corrected, the operation is brought back to step S22, and the process steps S22 to S26 are repeated until “No” is obtained in step S25.

If the place of the dangerous portion region which exists on the substrate is specified, it possible to examine the substrate efficiently in a short time by checking intensively the dangerous portion region in the inspecting process after the resist pattern formation.

That is, by setting a coordinate on the substrate and obtaining the coordinate for specifying the dangerous portion region previously, it possible to examine the resist pattern in a short time and efficiently by checking intensively the position on the substrate corresponding to the coordinate for specifying the dangerous portion region in the examination process after the resist pattern formation.

The FIG. 21 (contour map) is basically determined uniquely depending solely on the material and the depth position of the wiring layer existed in the substrate (wafer). That is, the FIG. 21 is uniquely depending for each era of the device. Therefore, the FIG. 21 is sufficient to prepare for every era of the manufactured device (product), need not to prepare for each kind of products on a massive scale. That is, the calculation or the experiment for obtaining the FIG. 21 is sufficient to conduct once for every era, not need to conduct repeatedly. Therefore, the evaluation method using the FIG. 21 is highly efficient.

### Fifth Embodiment

In the present embodiment, the evaluating method that carried out all by the simulation is explained.

Suppose a circuit pattern in a device of a certain era is being designed. Since the design rule for every era has already been determined, it is possible to know by referring to the design rule the thickness and the depth position as well as the material of each of the wiring layers included in the circuit pattern of the device that is to be manufactured.

The substrate (wafer) having the circuit pattern formed therein as designed is divided into a plurality of evaluation target regions (unit regions) described previously. Thereafter, the arrangement relations of the wiring layers which have been already formed in the plurality of evaluation target regions are plotted on the contour map shown in FIG. 20. As described previously, a pattern as designed is obtained by repeating the design of the pattern until the pattern to be corrected is eliminated based on the influence given by the wiring layers formed previously in the substrate to the wiring layers that are to be formed.

The series of all the operations described above can be performed by simulation even in the absence of the substrate (wafer) having a circuit pattern actually formed therein. Therefore, it is possible to save markedly the labor and the manufacturing cost by performing the series of all the operations without using an actual substrate and by preparing a software that produces a design after application of correction (a design in which the dangerous portion region is represented in a easily recognizable form).

The embodiments of the present invention have been explained, however, the present invention is not limited to the embodiments. For example, the evaluating method based on the back scattering coefficient η is explained in the embodiments, the evaluating method based on the back scattering radius βb can be performed as well, and similar effects are obtained. That is, by estimating the back scattering radius βb which varies in the substrate (wafer) based on the thickness and depth position of the wiring layer existed in the substrate (wafer), and the evaluating method having the similar effects as the evaluating method based on the back scattering coefficient η can be performed.

Also, the embodiments are directed to the case of employing the electron beam exposure, other charged particle beams such as an ion beam can be used.

Also, the lithography evaluating method of the embodiments described above can also be practiced as a computer program. That is, the computer program that executes the steps S1 to S3 (procedure) of the lithography evaluating method of the present embodiment in the FIGS. 3A and 3B or steps S11 to S14 (procedure) of the semiconductor device manufacturing method of the present embodiment in the FIG. 15 can be practice, Further, the computer program that executes the steps S21 to S26 (procedure) in the FIG. 22 can be practiced, too.

Also, as shown in FIG. 23, the present invention can be practiced as a computer program product storing a computer program product (e.g., CD-R0M, DVD) 42 having a program 41 for executing the lithography evaluating method of the present embodiments on a system including a computer 40.

That is, the computer program product is configured to store program instructions for execution on the computer system enabling the computer system to perform the operations of: reading in data relating to a substrate, the substrate including a semiconductor substrate and a wiring structure including at least one wiring layer formed on the semiconductor substrate; partitioning the substrate into a plurality of regions to be evaluated; and obtaining a value of property relating to the number and thickness of the at least one wiring layer included in the wiring structure previously and evaluating proximity effect on each of the plurality of regions to be evaluated.

The computer program product is configured to store program instructions for execution on the computer system enabling the computer system to perform the operations of: reading in data relating to a substrate, the substrate including a semiconductor substrate and a wiring structure including at least one wiring layer formed on the semiconductor substrate; and obtaining a relationship between property relating to the number and thickness of the at least one wiring layer and property relating to reflection energy on a surface of the substrate of charged particles reflected on the wiring structure when a resist formed on the substrate is irradiated with a charged particle beam previously, and obtaining a relationship between size error of a resist pattern to be formed on the substrate by lithography process using a charged particle beam and value of the property relating to the number and thickness of the at least one wiring layer based on the property relating to the number and thickness of the at least one wiring layer and the property relating to the reflection energy on the surface of the substrate of charged particles.

To be more specific, the computer program product includes the instructions corresponding to steps S1 to S3 in the FIGS. 3A and 3B or the instructions corresponding to steps S11 to S14 in the FIG. 15 in respect of the lithography evaluating method of the present embodiments. Further, the computer program product can include the other instructions included in the embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A lithography evaluating method comprising:
preparing a substrate, the substrate including a semiconductor substrate and a wiring structure including at least one wiring layer formed on the semiconductor substrate;
partitioning the substrate into a plurality of regions to be evaluated; and
obtaining a value of property relating to the wiring structure previously, and evaluating proximity effect on each of the plurality of regions to be evaluated based on the value of the property relating to the wiring structure.

2. The lithography evaluating method according to claim 1,
wherein the value of the property relating to the wiring structure is the number of the at least one wiring layer or the thickness of the at least one wiring layer, or both.

3. The lithography evaluating method according to claim 1,
wherein the value of the property relating to the wiring structure is the number of the at least one wiring layer which is given by the sum of “i” of Pi×ki, where Pi denotes depth position of the i-th wiring layer as viewed from a surface of the substrate, and ki denotes weight coefficient given to Pi.

4. The lithography evaluating method according to claim 1, further comprising:
estimating size error of a resist pattern to be formed on the substrate based on results of the obtaining the value of property relating to the wiring structure previously, and the evaluating proximity effect on each of the plurality of regions to be evaluated based on the value of the property relating to the wiring structure.

5. The lithography evaluating method according to claim 2, further comprising:
estimating size error of a resist pattern to be formed on the substrate based on results of the obtaining the value of property relating to the wiring structure previously, and the evaluating proximity effect on each of the plurality of regions to be evaluated based on the value of the property relating to the wiring structure.

6. The lithography evaluating method according to claim 3, further comprising:
estimating size error of a resist pattern to be formed on the substrate based on results of the obtaining the value of property relating to the wiring structure previously, and the evaluating proximity effect on each of the plurality of regions to be evaluated based on the value of the property relating to the wiring structure.

7. A lithography evaluating method comprising:
preparing a substrate, the substrate including a semiconductor substrate and a wiring structure including at least one wiring layer formed on the semiconductor substrate; and
obtaining a relationship between property relating to the number and thickness of the at least one wiring layer and property relating to reflection energy on a surface of the substrate of charged particles reflected on the wiring structure when a resist formed on the substrate is irradiated with a charged particle beam previously, and obtaining a relationship between size error of a resist pattern to be formed on the substrate by lithography process using a charged particle beam and value of the property relating to the number and thickness of the at least one wiring layer based on the property relating to the number and thickness of the at least one wiring layer and the property relating to the reflection energy on the surface of the substrate of charged particles.

8. The lithography evaluating method according to claim 7,
wherein the property relating to the reflection energy of the charged particles on the surface of the substrate is back scattering radius or back scattering coefficient of the charged particle beam.

9. The lithography evaluating method according to claim 7, further comprising:
expressing a dependency of the property relating to the reflection energy on the number and thickness of the at least one wiring layer in a three dimensional space, the three dimensional space being defined by three coordinate axes including a first coordinate axis provided by the number of the at least one wiring layer, a second coordinate axis provided by the thickness of the at least one wiring layers, and a third coordinate axis provided by the property relating to the reflection energy.

10. The lithography evaluating method according to claim 8, further comprising:
expressing a dependency of the property relating to the reflection energy on the number and thickness of the at least one wiring layer in a three dimensional space, the three dimensional space being defined by three coordinate axes including a first coordinate axis provided by the number of the at least one wiring layer, a second coordinate axis provided by the thickness of the at least one wiring layers, and a third coordinate axis provided by the property relating to the reflection energy.

11. The lithography evaluating method according to claim 7,
wherein the obtaining the relationship between the property relating to the number and thickness of the at least one wiring layer and the property relating to the reflection energy includes obtaining a dependency of the reflection energy on the number of the at least one wiring layer; and obtaining a dependency of the property relating to the reflection energy on the thickness of the at least one wiring layer.

12. The lithography evaluating method according to claim 8,
wherein the obtaining the relationship between the property relating to the number and thickness of the at least one wiring layer and the property relating to the reflection energy includes obtaining a dependency of the reflection energy on the number of the at least one wiring layer; and obtaining a dependency of the property relating to the reflection energy on the thickness of the at least one wiring layer.

13. The lithography evaluating method according to claim 7, further comprising:
extracting a value of the property relating to the number and thickness of the at least one wiring layer so that a value of the property relating to the reflection energy exceeds a predetermined value based on the relationship between the property relating to the number and thickness of the at least one wiring layer and the property relating to the reflection energy; and calculating the number and thickness of the at least one wiring layer corresponding to the extracted value of the property relating to the number and thickness of the at least one wiring layer.

14. The lithography evaluating method according to claim 8, further comprising:
extracting a value of the property relating to the number and thickness of the at least one wiring layer so that a value of the property relating to the reflection energy exceeds a predetermined value based on the relationship between the property relating to the number and thickness of the at least one wiring layer and the property relating to the reflection energy; and calculating the number and thickness of the at least one wiring layer corresponding to the extracted value of the property relating to the number and thickness of the at least one wiring layer.

15. A lithography evaluating method comprising:
preparing a substrate, the substrate including a semiconductor substrate and a wiring structure including at least one wiring layer formed on the semiconductor substrate;
partitioning the substrate into a plurality of regions to be evaluated; and
evaluating proximity effect on each of the plurality of regions to be evaluated based on a relationship between size error of a resist pattern to be formed on the substrate by lithography process using a charged particle beam and a value of property relating to the number and thickness of the at least one wiring layer.

16. The lithography evaluating method according to claim 15,
wherein the relationship between the size error of the resist pattern to be formed on the substrate by the lithography process using the charged particle beam and the value of the property relating to the number and thickness of the at least one wiring layer is obtained by using the obtaining property relating to the number and thickness of the at least wiring layer and property relating to reflection energy on a surface of the substrate of charged particles reflected on the wiring structure in anyone of claims 7 to 14.

17. (canceled)

18. (canceled)

19. A computer program product configured to store program instructions for execution on the computer system enabling the computer system to perform the operations of:
reading in data relating to a substrate, the substrate including a semiconductor substrate and a wiring structure including at least one wiring layer formed on the semiconductor substrate;
partitioning the substrate into a plurality of regions to be evaluated; and
obtaining a value of property relating to the number and thickness of the at least one wiring layer included in the wiring structure previously and evaluating proximity effect on each of the plurality of regions to be evaluated.

20. (canceled)
